(19) United States
(12) Patent Application Publication
(10) Pub. No.: US 2016/0322388 A1
(43) Pub. Date: Nov. 3, 2016

(54) ARRAY SUBSTRATE, ITS MANUFACTURING METHOD AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Jun MA, Beijing (CN); Yinhu HUANG, Beijing (CN); Chengshao YANG, Beijing (CN); Bingkun YIN, Beijing (CN); Junhao HAN, Beijing (CN)

(73) Assignees: BOE TECHNOLOGY GROUP CO., LTD., Beijing (CN); HEFEI XINSHENG OPTOELECTRONICS TECHNOLOGY CO., LTD., Anhui (CN)

(21) Appl. No.: 15/090,149

(22) Filed: Apr. 4, 2016

(30) Foreign Application Priority Data
Apr. 28, 2015 (CN) 201510209721.8

(51) Int. Cl. H01L 27/12; H01L 29/66

(52) U.S. Cl. CPC H01L 27/124; H01L 27/1225; H01L 29/66969; H01L 27/1259

(57) ABSTRACT

The present disclosure provides an array substrate, its manufacturing method and a display device. The array substrate includes a gate electrode, a gate insulation layer formed on the gate electrode, an active layer formed on the gate insulation layer, source/drain electrodes arranged at a layer identical to the active layer, and a pixel electrode arranged at a layer identical to the active layer. The active layer includes a metal oxide semiconductor, and the source/drain electrodes and the pixel electrode each include an ion-implanted metal oxide semiconductor.

### CROSS-REFERENCE TO RELATED APPLICATION

The present application claims a priority of the Chinese Patent Application No. 201510209721.8 filed on Apr. 28, 2015, which is incorporated herein by reference in its entirety.

### TECHNICAL FIELD

The present disclosure relates to the field of semiconductor display technology, in particular to an array substrate, its manufacturing method and a display device.

### BACKGROUND

Thin Film Transistor Liquid Crystal Display (TFT-LCD) has currently become a mainstream of flat-panel display devices due to its features such as small volume, low power consumption and being free of radiation, and a TFT array substrate is an important component of the TFT-LCD. A conventional a-Si TFT has relatively low electron mobility, so it is impossible to meet the requirements of a display product on high charge-discharge rate and high refresh rate. Oxide TFT, e.g., IGZO TFT, has the electron mobility dozens of times the a-Si TFT. When the TFT is manufactured by a metal oxide, it is able for the TFT to remarkably increase the charge-discharge rate for a pixel electrode, so as to increase a response speed of the TFT. Hence, the oxide TFT is a development trend for novel display devices.

Generally, a metal oxide TFT array substrate is manufactured by forming a metal gate electrode, a gate insulation layer, an oxide semiconductor layer, an etch stop layer, source/drain electrodes, a passivation layer and a pixel electrode sequentially on a glass substrate. During the manufacture, there are a large number of process steps as well as a large number of mask plates to be used, which leads to a deterioration in the product quality and a long manufacture time period.

### SUMMARY

An object of the present disclosure is to provide an array substrate, its manufacturing method and a display device, so as to reduce the process steps and shorten manufacture time period for the manufacture of the TFT.

In one aspect, the present disclosure provides in some embodiments an array substrate, including a gate electrode, a gate insulation layer formed on the gate electrode, an active layer formed on the gate insulation layer, source/drain electrodes arranged at a layer identical to the active layer, and a pixel electrode arranged at a layer identical to the active layer. The active layer includes a metal oxide semiconductor, and the source/drain electrodes and the pixel electrode each include an ion-implanted metal oxide semiconductor.

Alternatively, the array substrate further includes a gate line arranged at a layer identical to the gate electrode and a plurality of first data line sections arranged at a layer identical to the gate electrode and separated by the gate line.

Alternatively, the gate insulation layer includes via-holes opened to the first data line sections respectively, the array substrate further includes a second data line section arranged at a layer identical to the active layer, and the second data line section spans over the gate line and is connected at two ends to the adjacent first data line sections separated by the gate line through the via-holes.

Alternatively, the second data line section is of a width less than each of the first data line sections.

In another aspect, the present disclosure provides in some embodiments a display device including the above-mentioned array substrate.

In yet another aspect, the present disclosure provides in some embodiments a method for manufacturing an array substrate, including steps of: forming a gate electrode; forming a gate insulation layer on the gate electrode; forming a metal oxide semiconductor layer on the gate insulation layer; and subjecting a part of the metal oxide semiconductor layer to ion implantation, and patterning the metal oxide semiconductor layer, so as to form source/drain electrodes and a pixel electrode at a region where the metal oxide semiconductor layer is subjected to the ion implantation, and form an active layer at a region where the metal oxide semiconductor layer is not subjected to the ion implantation.

Alternatively, the method further includes forming a plurality of first data lines and a gate line at a layer identical to the gate electrode while forming the gate electrode, the plurality of first data line sections being separated by the gate line.

Alternatively, the method further includes forming via-holes in the gate insulation layer and opened to the first data line sections respectively. The step of patterning the metal oxide semiconductor layer further includes forming a second data line section which spans over the gate line and is connected at two ends to the adjacent first data line sections separated by the gate line through the via-holes.

Alternatively, the ion implantation is hydrogen ion implantation.

Alternatively, the second data line section is of a width less than each of the first data line sections.

According to the embodiments of the present disclosure, the source/drain electrodes, the active layer and the pixel electrode are arranged at an identical layer, so they may be formed by merely one mask plate and one etching process. As a result, it is able to reduce the process steps and shorten the manufacture time period, thereby to improve the yield. In addition, it is also able to reduce a coupling capacitance between the data line section and the gate line by reducing a width of a portion of the data line section where the data line section is connected to the gate line.

### BRIEF DESCRIPTION OF THE DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a top view of an array substrate according to one embodiment of the present disclosure;

FIG. 2 is a sectional view of the array substrate along Line A-A′ in FIG. 1;

FIG. 3 is another sectional view of the array substrate along Line B-B′ in FIG. 1;

FIG. 4 is flow chart of a method for manufacturing the array substrate according to one embodiment of the present disclosure;

FIG. 5 is another flow chart of the method for manufacturing the array substrate according to one embodiment of the present disclosure;

FIG. 6 is a schematic view showing a gate electrode, a gate line and first data lines section along line A-A′ according to one embodiment of the present disclosure;

FIG. 7 is another schematic view showing the gate electrode, the gate line and the first data line sections along line B-B′ according to one embodiment of the present disclosure;

FIG. 8 is a schematic view showing a gate insulation layer and via-holes along line A-A′ according to one embodiments of the present disclosure;

FIG. 9 is another schematic view showing the gate insulation layer and the via-holes along line B-B′ according to one embodiment of the present disclosure;

FIG. 10 is a schematic view showing a metal oxide semiconductor layer along line A-A′ according to one embodiment of the present disclosure;

FIG. 11 is another schematic view showing the metal oxide semiconductor layer along line B-B′ according to one embodiment of the present disclosure;

FIG. 12 is a schematic view showing the first data line sections, source/drain electrodes, a pixel electrode and an active layer along line A-A′ according to one embodiment of the present disclosure; and

FIG. 13 is another schematic view showing the first data line sections, the source/drain electrodes, the pixel electrode and the active layer along line B-B′ according to one embodiment of the present disclosure.

### DETAILED DESCRIPTION OF THE EMBODIMENTS

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

The present disclosure provides in some embodiments an array substrate which, as shown in FIGS. 1-3, includes a gate electrode 2, a gate insulation layer 3 formed on the gate electrode 2, an active layer 60 formed on the gate insulation layer 3, source/drain electrodes 51, 52 arranged at a layer identical to the active layer 60, and a pixel electrode 70 arranged at a layer identical to the active layer 60. The active layer 60 includes a metal oxide semiconductor, and the source/drain electrodes 51, 52 and the pixel electrode 70 each include an ion-implanted metal oxide semiconductor.

According to the array substrate in the embodiments of the present disclosure, the source/drain electrodes, the active layer and the pixel electrode are arranged at an identical layer, so they may be formed by merely one mask plate and one etching process. As a result, it is able to reduce the process steps and shorten the manufacture time period, thereby to improve the yield. In addition, it is also able to reduce a coupling capacitance between a data line section and the gate line by reducing a width of a portion of the data line section where the data line section is connected to the gate line.

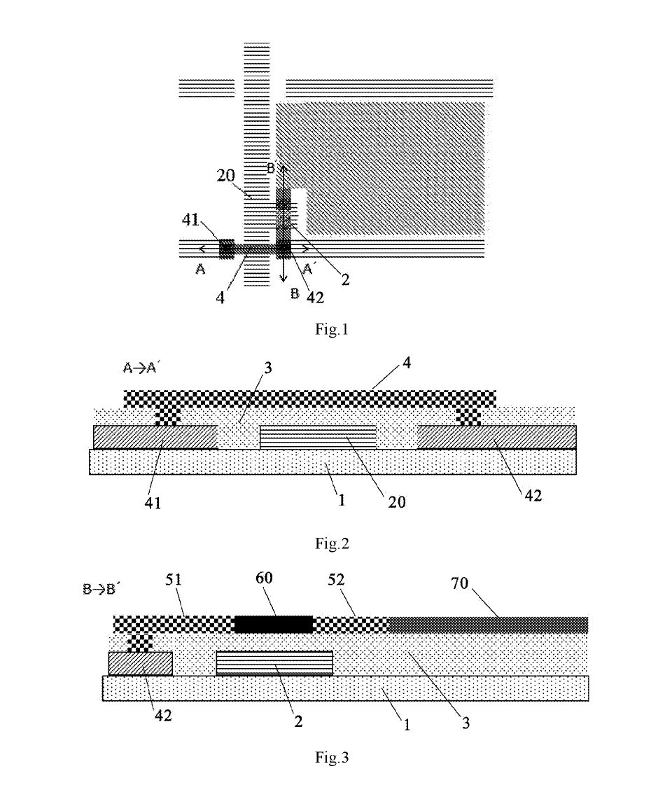

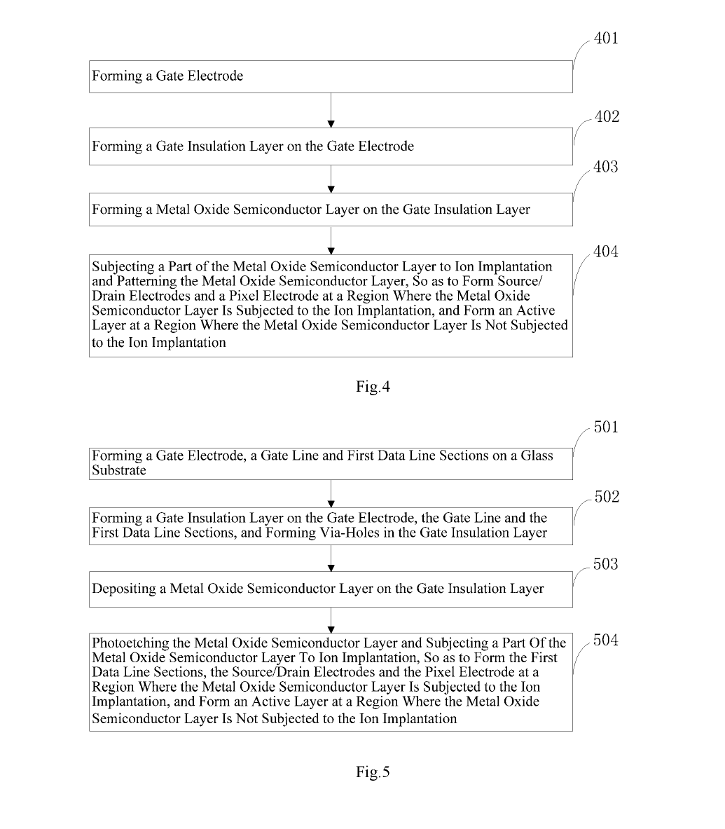

FIG. 1 is a top view of the array substrate, FIG. 2 is a sectional view of the array substrate along line A-A′, and FIG. 3 is another sectional view of the array substrate along line B-B′. In FIGS. 1-3, the reference numeral 1 represents a substrate, e.g., a glass substrate.

Alternatively, the array substrate may further include first data line sections 41, 42 arranged at a layer identical to the gate electrode 2.

Alternatively, the gate insulation layer 3 may further include via-holes opened to the first data line sections 41, 42, respectively.

Alternatively, the array substrate may further include a gate line 20 arranged at a layer identical to the gate electrode 2, and a second data line section 4 arranged at a layer identical to the active layer 60. The second data line section 4 spans over the gate line 20 and is connected, at its two ends, to the first data line sections 41, 42 separated by the gate line 20 through the via-holes.

Alternatively, the second data line section 4 may be of a width less than the first data line sections 41, 42. In this way, it is able to reduce a coupling capacitance between the data line section and the gate line by reducing the width of a portion of the data line section where the data line section is connected to the gate line.

The present disclosure further provides in some embodiments a display device which includes the above-mentioned array substrate. The display device may be any device having a display function, such as a television, a display, a flat-panel computer, a digital photo frame, a navigator, an electronic paper or a mobile telephone.

The present disclosure further provides in some embodiments a method for manufacturing an array substrate which, as shown in FIG. 4, includes Step 401 of forming a gate electrode, Step 402 of forming a gate insulation layer on the gate electrode, Step 403 of forming a metal oxide semiconductor layer on the gate insulation layer, and Step 404 of subjecting a part of the metal oxide semiconductor layer to ion implantation, and patterning the metal oxide semiconductor layer, so as to form source/drain electrodes and a pixel electrode at a region where the metal oxide semiconductor layer is subjected to the ion implantation, and form an active layer at a region where the metal oxide semiconductor layer is not subjected to the ion implantation.

According to the method in the embodiments of the present disclosure, the source/drain electrodes, the active layer and the pixel electrode are arranged at an identical layer, so they may be formed by merely one mask plate and one etching process. As a result, it is able to reduce the process steps and shorten the manufacture time period, thereby to improve the yield. In addition, it is also able to reduce a coupling capacitance between the data line section and the gate line by reducing a width of a portion of the data line section where the data line section is connected to the gate line.

Alternatively, the method may further include forming first data line sections while forming the gate electrode.

Alternatively, the method may further include forming via-holes in the gate insulation layer and opened to the first data line sections respectively.

Alternatively, the method may further include forming a gate line while forming the gate electrode, and the step of patterning the metal oxide semiconductor layer may further include forming a second data line section which spans over the gate line and is connected at two ends to the first data line sections separated by the gate line through the via-holes.

Alternatively, the ion implantation may be hydrogen ion implantation.

Alternatively, the second data line section may be of a width less than each of the first data line sections.

The method for manufacturing the array substrate will be described hereinafter in more details.

As shown in FIG. 5, the method may include the following steps.

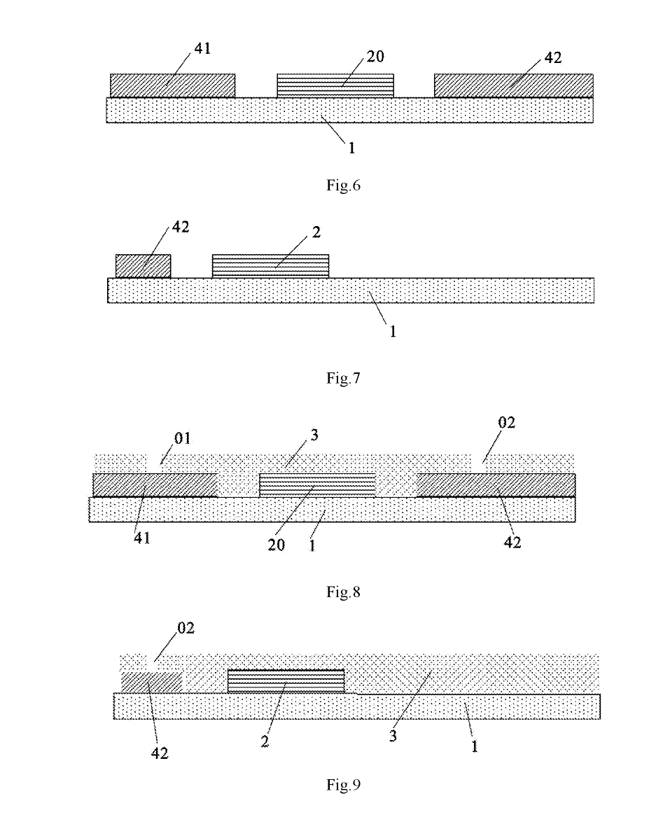

Step 501: forming the gate electrode, the gate line and the first data line sections on the glass substrate. In this step, referring to FIGS. 6 and 7, a gate metal layer may be deposited on the glass substrate 1, and then patterned by masking, exposing and etching, so as to form the gate electrode 2, the gate line 20 and the first data line sections 41, 42.

Step 502: forming the gate insulation layer on the gate electrode, the gate line and the first data line sections, and forming the via-holes in the gate insulation layer. In this step, the gate insulation layer 3 may be deposited on the gate electrode 2, the gate line 20 and the first data line sections 41, 42, and the via-holes 01, 02 may be formed in the gate insulation layer 3 and opened to the first data line sections 41, 42 by masking, exposing and etching, as shown in FIGS. 8 and 9.

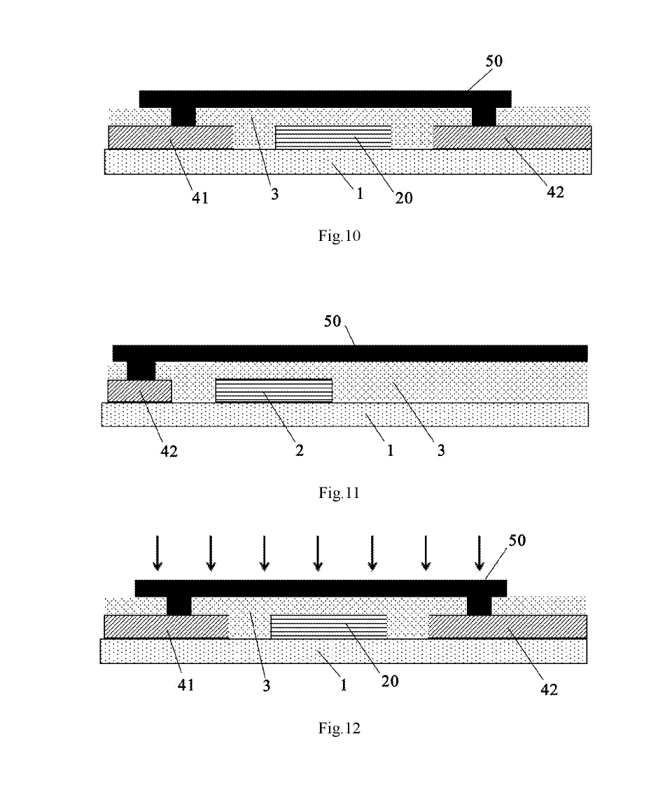

Step 503: depositing the metal oxide semiconductor layer on the gate insulation layer. In this step, the metal oxide semiconductor layer 50 may be deposited on the gate insulation layer 3, as shown in FIGS. 10 and 11.

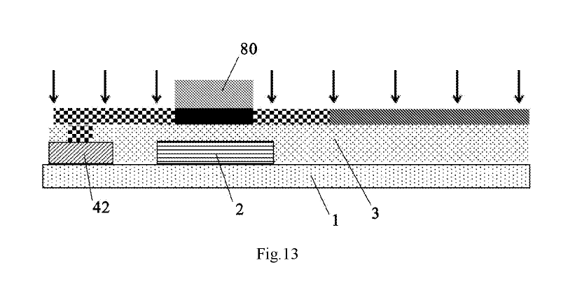

Step 504: photoetching the metal oxide semiconductor layer and subjecting a part of the metal oxide semiconductor layer to the ion implantation, so as to form the second data line sections, the source/drain electrodes and the pixel electrode at a region where the metal oxide semiconductor layer is subjected to the ion implantation, and form the active layer at a region where the metal oxide semiconductor layer is not subjected to the ion implantation. In this step, a photoresist with different thicknesses may be formed on the semiconductor layer 50 through a halftone mask plate, and then etched so as to form the regions corresponding to the second data line section, the active layer, the source/drain electrodes and the pixel electrode, as shown in FIGS. 12 and 13. Then, the regions corresponding to the second data line section, the source/drain electrodes and the pixel electrode are subjected to the ion implantation, so as to enable them to be conductive. For example, the regions may be subjected to hydrogen ion implantation so as to form the second data line section 4, the source/drain electrodes 51, 52, and the pixel electrode 70.

At this time, the photoresist 80 is still reserved at a region right above the gate electrode 2, and thus this region is not subjected to the ion implantation (as shown in FIG. 13). After the photoresist at this region is removed, the active layer 60 is formed at this region. FIGS. 1-3 show the resultant array substrate.

According to method in the embodiments of the present disclosure, the array substrate may be formed using merely three mask plates. As a result, it is able to reduce the process steps and shorten the manufacture time period, thereby to improve the yield. In addition, it is also able to reduce a coupling capacitance between the data line section and the gate line by reducing a width of a portion of the data line section where the data line section is connected to the gate line.

The above are merely the preferred embodiments of the present disclosure. It should be appreciated that, a person skilled in the art may make further modifications and improvements without departing from the spirit of the present disclosure, and these modifications and improvements shall also fall within the scope of the present disclosure.

What is claimed is:

1. An array substrate, comprising:
a gate electrode;
a gate insulation layer formed on the gate electrode;
an active layer formed on the gate insulation layer;
source/drain electrodes arranged at a layer identical to the active layer; and
a pixel electrode arranged at a layer identical to the active layer,
wherein the active layer comprises a metal oxide semiconductor, and the source/drain electrodes and the pixel electrode each comprise an ion-implanted metal oxide semiconductor.

2. The array substrate according to claim 1, further comprising:
a gate line arranged at a layer identical to the gate electrode; and
a plurality of first data line sections arranged at a layer identical to the gate electrode and separated by the gate line.

3. The array substrate according to claim 2, wherein the gate insulation layer comprises via-holes opened to the first data line sections respectively,
the array substrate further comprises a second data line section arranged at a layer identical to the active layer, and
the second data line section spans over the gate line and is connected at two ends to the adjacent first data line sections separated by the gate line through the via-holes.

4. The array substrate according to claim 3, wherein the second data line section is of a width less than each of the first data line sections.

5. A display device comprising the array substrate according to claim 1.

6. The display device according to claim 5, wherein the array substrate further comprises:
a gate line arranged at a layer identical to the gate electrode; and
a plurality of first data line sections arranged at a layer identical to the gate electrode and separated by the gate line.

7. The display device according to claim 6, wherein the gate insulation layer comprises via-holes opened to the first data line sections respectively,
the array substrate further comprises a second data line section arranged at a layer identical to the active layer, and
the second data line section spans over the gate line and is connected at two ends to the adjacent first data line sections separated by the gate line through the via-holes.

8. The display device according to claim 7, wherein the second data line section is of a width less than each of the first data line sections.

9. A method for manufacturing an array substrate, comprising steps of:
forming a gate electrode;
forming a gate insulation layer on the gate electrode;
forming a metal oxide semiconductor layer on the gate insulation layer; and
subjecting a part of the metal oxide semiconductor layer to ion implantation, and patterning the metal oxide semiconductor layer, so as to form source/drain electrodes and a pixel electrode at a region where the metal oxide semiconductor layer is subjected to the ion implantation, and form an active layer at a region where the metal oxide semiconductor layer is not subjected to the ion implantation.

10. The method according to claim 9, further comprising:
forming a plurality of first data lines and a gate line at a layer identical to the gate electrode while forming the gate electrode, the plurality of first data line sections being separated by the gate line.

11. The method according to claim 10, further comprising:
forming via-holes in the gate insulation layer, the via-holes being opened to the first data line sections respectively,
wherein the step of patterning the metal oxide semiconductor layer further comprises forming a second data line section which spans over the gate line and is connected at two ends to the adjacent first data line sections separated by the gate line through the via-holes.

12. The method according to claim 11, wherein the second data line section is of a width less than each of the first data line sections.

13. The method according to claim 9, wherein the ion implantation is hydrogen ion implantation.

14. The method according to claim 10, wherein the ion implantation is hydrogen ion implantation.

15. The method according to claim 11, wherein the ion implantation is hydrogen ion implantation.

16. The method according to claim 12, wherein the ion implantation is hydrogen ion implantation.
